(19) United States
(12) Patent Application Publication
(10) Pub. No.: US 2010/0078697 A1
(43) Pub. Date: Apr. 1, 2010

(54) Semiconductor device including capacitor and method for manufacturing the same

(75) Inventor: Kenichi Sugino, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/585,740

(22) Filed: Sep. 23, 2009

(30) Foreign Application Priority Data
Sep. 30, 2008 (JP) 2008-252908

(51) Int. Cl. H01L 27/108; H01L 21/8242

(52) U.S. Cl. 257/296; 438/393; 257/E21.646; 257/E27.084

(57) ABSTRACT

A semiconductor device according to the present invention uses a capacitor including a capacitive insulating film sandwiched between an upper electrode and a lower electrode. The lower electrode of the capacitor is constructed by overlappingly connecting a plurality of electrode portions together. A lower electrode portion (plug type electrode) of the adjacent electrode portions is made of columnar tungsten. The lower electrode portion further includes a conductive film (barrier film) that covers a side surface and a bottom surface of the tungsten. A top surface of the tungsten is covered with a bottom portion of an upper electrode portion (cylinder type electrode).

This application is based upon and claims the benefit of priority from Japanese patent application No. 2008-252908, filed on Sep. 30, 2008, the disclosure of which is incorporated herein in its entirety by reference.

### BACKGROUND OF THE INVENTION

1. Field of the Invention

The present invention relates to a semiconductor device including a capacitor, and in particular, to a semiconductor device including a capacitor having a lower electrode constructed by overlappingly connecting a plurality of electrode portions together, as well as a method for manufacturing the semiconductor device.

2. Description of Related Art

For semiconductor devices such as DRAMs which perform a storing operation using capacitor elements, memory cell size has been reduced as a result of advanced miniaturization. Thus, for semiconductor devices including capacitors, efforts have been made to develop a capacitor that has increased capacitance and that minimizes with an increase in occupancy area.

The capacitor is configured such that a capacitive insulating film is sandwiched between a lower electrode and an upper electrode. In order to increase the capacitance value of the capacitor, general efforts focus on an increase in the height of the lower electrode and thus the surface area of the capacitor. However, this method makes manufacturing difficult.

Thus, to facilitate the manufacturing, Japanese Patent Laid-Open No. 2004-311918 (hereinafter referred to as Patent Document 1) proposes a lower electrode of a capacitor that is constructed by overlappingly connecting a plurality of electrode portions together.

A capacitor having a lower electrode of a 2-stage structure and typified by Patent Document 1 will be described with reference to FIG. 1.

Insulating film 101 is formed on semiconductor substrate 100. Plug type electrode 104 serving as a lower stage of the lower electrode of the capacitor is provided in insulating film 101. Plug type electrode 104 is formed of conductive film 102 and tungsten (W) 103. Cylinder type electrode 105 serving as an upper stage of the lower electrode of the capacitor is provided so as to connect to the top portion of plug type electrode 104.

Furthermore, although not shown in the drawings, a capacitive insulating film and an upper electrode included in the capacitor are provided in this order so as to cover the exposed surfaces of plug type electrode 104 and cylinder type electrode 105.

In the lower electrode of the capacitor of the 2-stage configuration as shown in FIG. 1, owing to processing restrictions, the size of the bottom portion of cylinder type electrode 105 that forms the upper stage of the lower electrode of the capacitor is generally smaller than that of the top portion of cylinder type electrode 105. Furthermore, when plug type electrode 104 and cylinder type electrode 105 are separately formed, misalignment may occur. As a result, portion 110 from which tungsten 103 is exposed is formed in the connection portion between plug type electrode 104 and cylinder type electrode 105. When a capacitive insulating film is formed in this condition, exposed portion 110 of tungsten is oxidized to form an intervening layer of tungsten oxide between the capacitive insulating film and tungsten 103.

The intervening layer may increase leakage current from the capacitor and reduce the capacitance value.

Thus, it has disadvantageously been difficult to produce a high-performance semiconductor device such as a DRAM which offers excellent data holding properties (refresh property) by using the capacitor that has a lower electrode of 2-stage structure.

### SUMMARY

The present invention seeks to solve the above problems.

In one embodiment, there is provided the following semiconductor device. That is, the semiconductor device uses a capacitor including a capacitive insulating film sandwiched between an upper electrode and a lower electrode. The lower electrode of the capacitor is constructed by overlappingly connecting a plurality of electrode portions together. A lower electrode portion of the adjacent electrode portions comprises columnar tungsten. The lower electrode portion further comprises a conductive film covering a side surface and a bottom surface of the tungsten. A top surface of the tungsten is covered with a bottom portion of an upper-electrode portion.

In another embodiment, there is provided a method for manufacturing a semiconductor device as described below.

The manufacturing method comprises:

preparing a semiconductor substrate with an active region formed in a surface portion thereof;

forming a first interlayer insulating film on the semiconductor substrate;

forming a contact hole in the first interlayer insulating film;

forming a barrier film on an inner surface of the contact hole;

filling tungsten inside the contact hole with the barrier film formed therein;

forming a second interlayer insulating film on the first interlayer insulating film so that the second interlayer insulating film covers a plug type electrode (lower electrode portion) comprising the barrier film and the tungsten;

forming an opening in the second interlayer insulating film and immediately above the plug type electrode;

removing an upper portion of the tungsten in the plug type electrode through the opening to form a cavity portion in an upper portion of the plug type electrode;

forming a conductive film serving as a cylinder type electrode (upper electrode portion), on a side surface of the opening and an inner surface of the cavity portion;

removing the first interlayer insulting film and the second interlayer insulating film so as to expose all of the cylinder type electrode and a part of the plug type electrode;

forming a capacitive insulating film over exposed surfaces of the cylinder type electrode and the plug type electrode; and

forming a conductive film serving as an upper electrode of the capacitor so that the conductive film covers the capacitive insulating film.

In the present invention, the tungsten, the member that forms the lower electrode portion of the lower electrode of the capacitor, is covered not only with the conductive film at the side and bottom surface thereof but also with the conductive film that forms the upper electrode portion of the lower electrode, at the top surface thereof. This prevents the tungsten that forms the lower electrode portion from directly contacting the capacitive insulating film. As a result, leakage current from the capacitor can be reduced.

According to the present invention, the tungsten that forms the lower electrode portion of the lower electrode of the capacitor is covered with the component of the electrode portion that forms the upper stage of the lower electrode. This prevents the tungsten from directly contacting the capacitive insulating film. Thus, leakage current from the capacitor can be reduced.

In the specification and the claims, the terms “upper (top)” and “lower (bottom)” refer to directions in which the components are stacked with respect to the principal surface of the semiconductor substrate.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a sectional view showing a capacitor including a lower electrode of 2-stage structure as typified by Patent Document 1;

FIG. 2 is a sectional view showing that a set of components including a lower electrode of a capacitor have been formed on a prepared semiconductor substrate in the semiconductor device according to the present invention;

FIG. 3 is a sectional view illustrating a process of manufacturing a capacitor according to a first embodiment of the present invention;

FIG. 4 is a sectional view illustrating the process of manufacturing the capacitor according to the first embodiment of the present invention;

FIG. 5 is a sectional view illustrating the process of manufacturing the capacitor according to the first embodiment of the present invention;

FIG. 6 is a sectional view illustrating the process of manufacturing the capacitor according to the first embodiment of the present invention;

FIG. 7 is a sectional view illustrating the process of manufacturing the capacitor according to the first embodiment of the present invention;

FIG. 8 is a sectional view illustrating the process of manufacturing the capacitor according to the first embodiment of the present invention;

FIG. 9 is a sectional view illustrating the process of manufacturing the capacitor according to the first embodiment of the present invention;

FIG. 10 is a sectional view illustrating a process of manufacturing a capacitor according to a second embodiment of the present invention;

FIG. 11 is a sectional view illustrating the process of manufacturing the capacitor according to the second embodiment of the present invention;

FIG. 12 is a sectional view illustrating a process of manufacturing a capacitor according to a third embodiment of the present invention;

FIG. 13 is a plan view schematically showing a part of a memory cell in a DRAM which is an example of a semiconductor device according to the present invention; and

FIG. 14 is a sectional view of a memory cell in a completed DRAM, showing a portion corresponding to a cross section taken along portion A-A' in FIG. 12.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

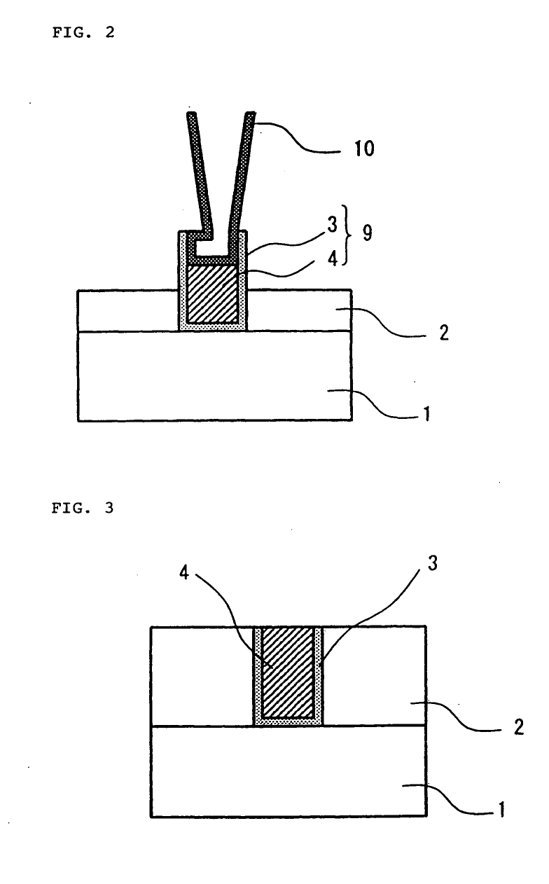

FIG. 2 is a sectional view showing that a set of components including a lower electrode (a first electrode) of a capacitor have been formed on a prepared semiconductor substrate in the semiconductor device according to the present invention.

Referring to FIG. 2, a lower electrode of a capacitor constructed by overlappingly connecting plug type electrode 9 and cylinder type electrode 10 is formed on semiconductor substrate 1.

More specifically, interlayer insulating film 2 such as a silicon oxide film (SiO₂) is formed on semiconductor substrate 1. Moreover, plug type electrode 9 that forms a lower stage of the lower electrode of the capacitor is formed in interlayer insulating film 2.

Plug type electrode 9 is formed of cup-shaped barrier film 3 that is formed on an inner wall surface of a contact hole that is open in interlayer insulating film 2, and tungsten 4 that is filled inside barrier film 3. In other words, electrode 9 is composed of a column of a conductive material such as tungsten 4 and barrier film 3 formed between columnar tungsten 4 and both the side and bottom surfaces of the contact hole. Barrier film 3 is composed of a film (TiN/Ti) that is obtained by stacking titanium nitride (TiN) and titanium (Ti).

Moreover, cylinder type electrode 10 that forms the lower stage of the lower electrode of the capacitor is provided in the upper part of plug type electrode 9. Cylinder type electrode 10 is formed of a cylindrical stack film (TiN/Ti) obtained by stacking titanium nitride and titanium in the form of a boot.

In the present invention, plug type electrode 9 includes a recess in the upper portion thereof; the recess is formed by the top surface of tungsten 4 and barrier film 3. The bottom portion of cylinder type electrode 10 is located in the recess so as to cover the top surface of tungsten 4.

A plurality of lower electrodes for a capacitor configured as described above are provided in the semiconductor device according to the present invention.

Active regions (not shown in the drawings) partitioned by isolation regions are formed in the surface portion of semiconductor substrate 1. Each of the active regions is electrically connected to plug type electrode 9.

Then, a method for manufacturing a capacitor in a semiconductor device according to the present invention will be described with reference to the drawings.

As shown in FIG. 3, semiconductor substrate 1 with active regions each having a desired shape (not shown in the drawings) that is formed in the surface portion thereof is prepared. Then, interlayer insulating film 2 such as a silicon oxide film is formed on substrate 1. A contact hole is then formed in a region in which plug type electrode 9 is to be formed. Barrier film 3 composed of a stack film of titanium nitride and titanium is so formed to a film thickness that the interior of the contact hole is not completely filled with barrier film 3.

Subsequently, tungsten (W) 4 is formed by a CVD method so as to fill the interior of an opening formed by barrier film 3. Then, together with the top surface portion of interlayer insulating film 2, barrier film 3 and tungsten 4 are removed by a CMP (Chemical Mechanical Polishing) method or dry etching.

Between each of the active regions formed in the surface of the semiconductor substrate and barrier film 3, a plug with another conductivity may be provided to electrically connect the active region and barrier film 3 together.

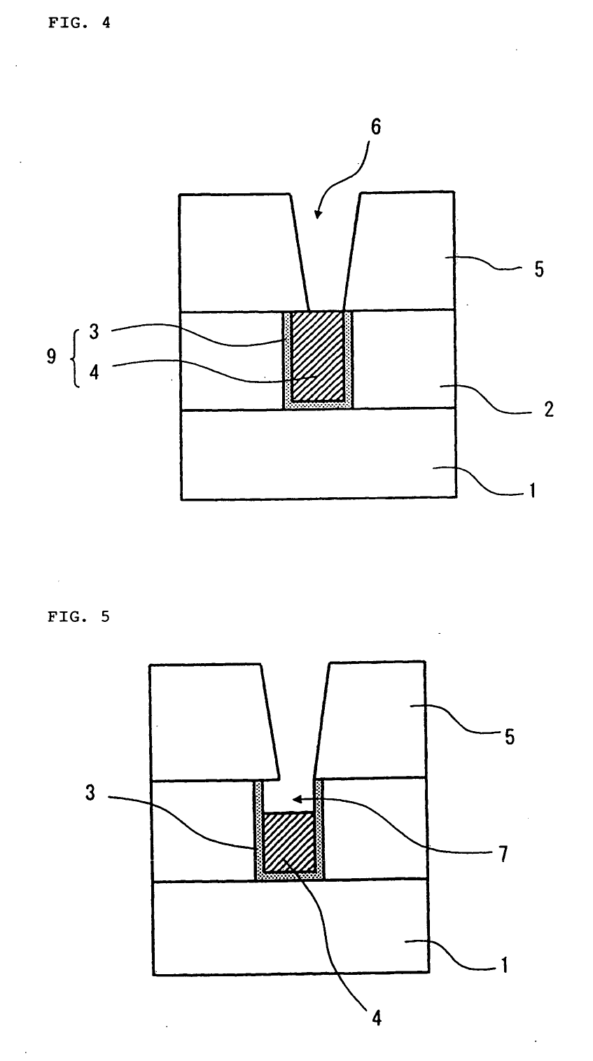

Subsequently, as shown in FIG. 4, interlayer insulating film 5 is formed using a silicon oxide film or the like so as to cover the top surface of plug type electrode 9 composed of barrier film 3 and tungsten 4. Thereafter, interlayer insulating film 5 on plug type electrode 9 is partly removed to form opening 6 in which tungsten 4 is exposed. Owing to processing restrictions, opening 6 is tapered such that the size of the bottom portion of the hole is smaller than that of the top portion thereof.

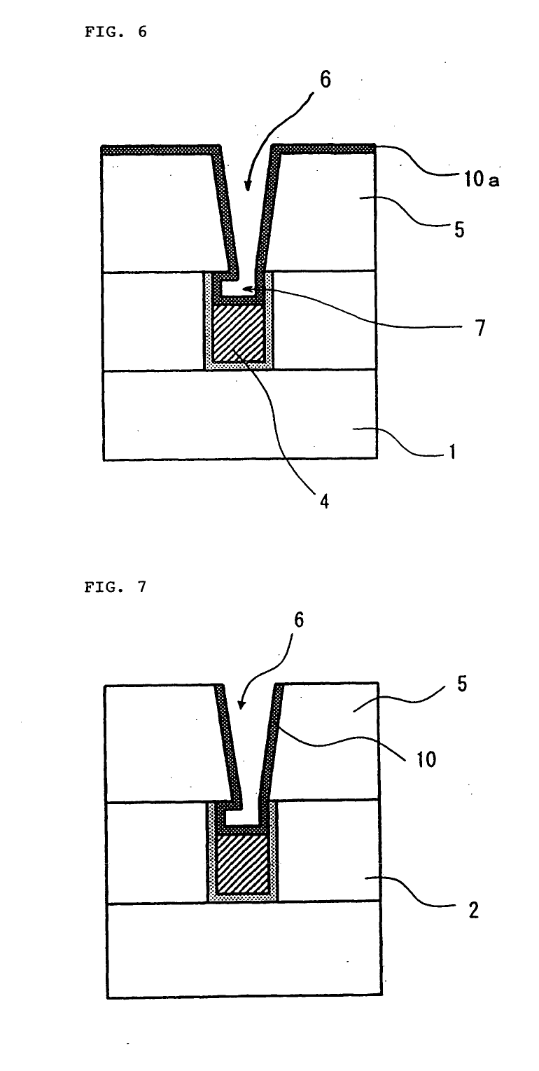

Moreover, as shown in FIG. 5, the upper portion of tungsten 4 is removed under the conditions that etching selectivity for tungsten 4 is higher than that for barrier film 3 and that the tungsten is isotropically etched. Specifically, dry etching may be performed at a pressure of 15 to 20 mTorr (about 2.0 to 2.7 Pa) using SF₆ and Ar as an etching gas. Thus, tungsten 4 is removed and barrier film 3 is left. As a result, cavity 7 (recess) is formed. The amount (recess amount) by which the tungsten is removed preferably corresponds to about 15 to 25% of the height of plug type electrode 9 from the surface of semiconductor substrate 1.

Subsequently, as shown in FIG. 6, the CVD method is used to form conductive film 10a composed of a stack film (TiN/Ti) of titanium nitride and titanium, on the top surface portion of interlayer insulating film 5 and inside opening 6 and cavity 7 in barrier film 3. In a reduced pressure condition, conductive film 10a can be formed so as to cover the entire inner wall surface (that is, exposed surfaces of both tungsten 4 and barrier film 3) of cavity 7 that was previously formed.

Moreover, as shown in FIG. 7, conductive film 10a on the top surface portion of interlayer insulating film 5 is removed by dry etching. At this time, to protect conductive film 10a inside opening 6, dry etching may be performed after opening 6 has been filled with a photo resist film or the like. Conductive film 10a that has been formed in this step finally functions as cylinder type electrode 10 that forms the upper stage of the lower electrode of the capacitor.

Subsequently, as shown in FIG. 8, wet etching is used to remove interlayer insulating films 5 and 2 to expose all of cylinder type electrode 10 and a part of plug type electrode 9. For the removal of interlayer insulating film 2, conditions for the wet etching are adjusted so as to leave an appropriate film thickness to prevent the lower electrode of the capacitor from collapsing during the manufacturing process.

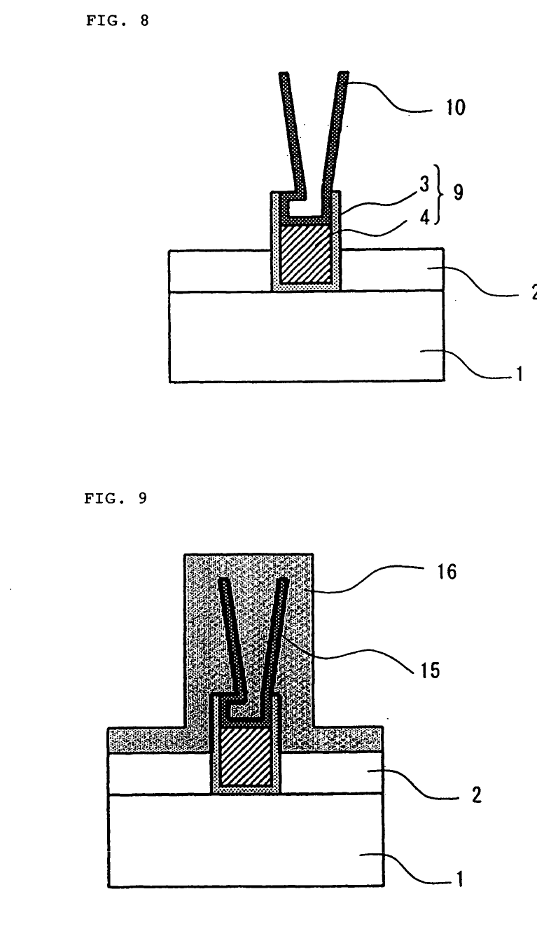

Moreover, as shown in FIG. 9, capacitive insulating film 15 is formed on interlayer insulating film 2 using the CVD method so as to cover the exposed surface of both plug type electrode 9 and cylinder type electrode 10 which form the lower electrode of the capacitor. For example, an oxide of hafnium (Hf) or zirconium (Zr) may be used as capacitive insulating film 15.

Thereafter, conductive film 16 that functions as an upper electrode (a second electrode) of the capacitor is formed by the CVD method to complete a capacitor.

A material for conductive film 16 that serves as the upper electrode of the capacitor is not particularly limited, but may be, for example, a titanium nitride film or a stack film that contains titanium nitride.

Furthermore, conductive film 10a that forms cylinder type electrode 10 and barrier film 3, a component of plug type electrode 9, need not necessarily be formed of the same material.

In the capacitor produced by the above-described manufacturing process, as shown in FIG. 2, the peripheral surface (top and side surfaces) of tungsten 3 is covered with barrier film 3 and the conductive film that forms cylinder type electrode 10. This prevents the tungsten from being exposed. Thus, when capacitive insulating film 15 is formed, the above-described configuration prevents formation of an intervening layer of tungsten oxide between capacitive insulating film 15 and tungsten 3. Consequently, possible leakage current between the upper electrode and lower electrode of the capacitor can be inhibited.

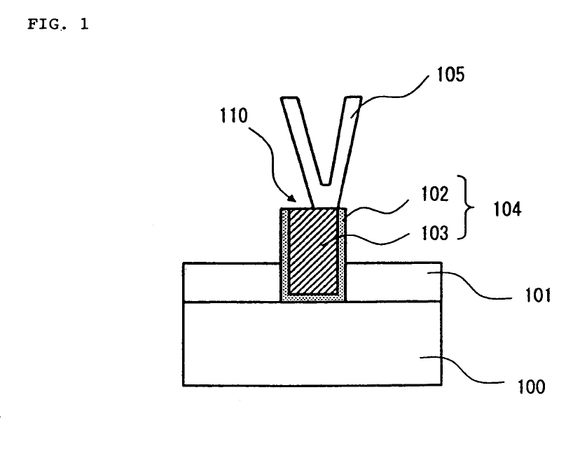

Furthermore, compared to the conventional lower electrode (FIG. 1), the present lower electrode allows an increase in the surface area of cylinder type electrode 10 and thus in the amount of capacitive insulating film. This is effective for increasing the capacitance value of the capacitor.

Moreover, compared to the conventional lower electrode (FIG. 1), the present lower electrode is configured such that in the connection portion between plug type electrode 9 and cylinder type electrode 10, electrodes 9 and 10 are fitted to each other. This improves connection strength. Thus, the lower electrode of the capacitor is inhibited from collapsing during manufacturing. Consequently, compared to the related art, the present embodiment facilitates the manufacturing.

### Second Embodiment

Now, a second embodiment of the present invention will be described.

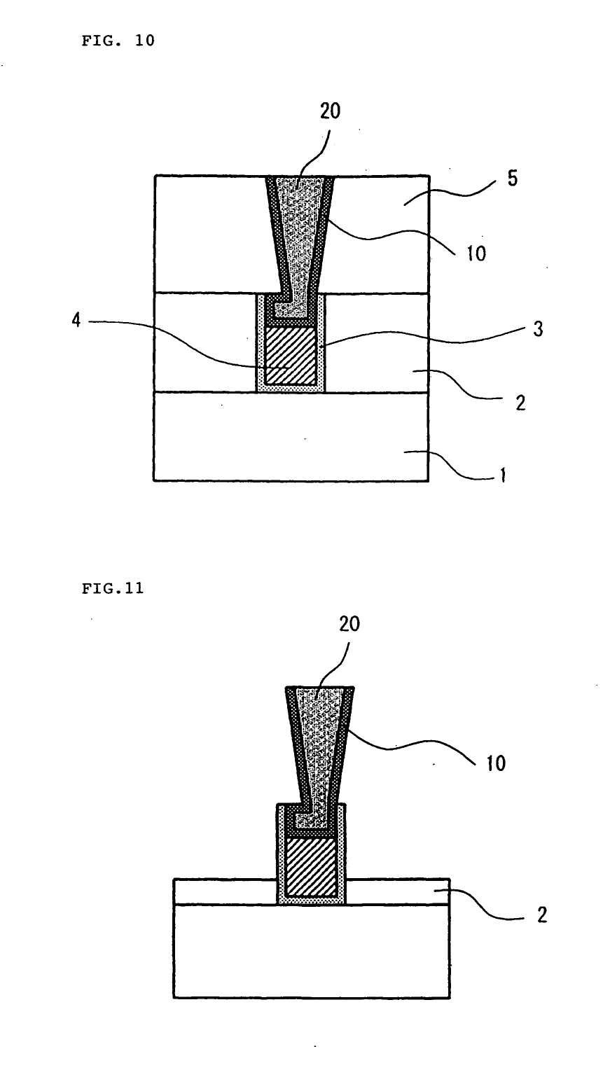

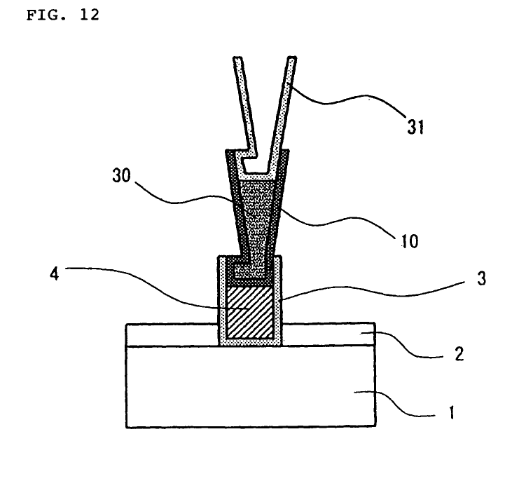

A process of manufacturing a capacitor according to the present embodiment is the same as that according to the first embodiment from the beginning to a halfway step, that is, the steps shown in FIGS. 3 to 7 are common to both processes. The two processes are different in the subsequent steps. Here, the steps subsequent to the one shown in FIG. 7 will be described with reference to FIGS. 10 and 11.

After the step shown in FIG. 7, as shown in FIG. 10, silicon nitride film (Si₃N₄) 20 as an insulating material is formed by the CVD method so as to fill the interior of opening 6. Thereafter, the silicon nitride film on the top surface portion of interlayer insulating film 5 is removed.

Subsequently, as shown in FIG. 11, interlayer insulating films 5 and 2 are removed using wet etching to expose all of cylinder type electrode 10 and a part of plug type electrode 9. In order to remove interlayer insulating film 2, conditions for wet etching are adjusted so as to leave an appropriate film thickness to prevent the lower electrode of the capacitor from being collapsing during the manufacturing process.

Thereafter, a capacitive insulating film and an upper electrode are formed as in the case of the first embodiment (see FIG. 9) to complete the process of manufacturing a capacitor.

In the present embodiment, the interior of cylinder type electrode 10 is filled with silicon nitride film 20. Thus, compared to the first embodiment, the present embodiment allows the strength of cylinder type electrode 10 to be improved. Consequently, even when having an increased height, cylinder type electrode 10 can be inhibited from collapsing. This facilitates an increase in the capacitance value of the capacitor.

Furthermore, in the step shown in FIG. 10, the silicon nitride film on the top surface portion of interlayer insulating film 5 may be partly left on interlayer insulating film 5 in linear form instead of being completely removed. Thus, the linear film can be utilized as a support film for preventing the lower electrode from collapsing during wet etching in the step shown in FIG. 11.

### Third Embodiment

In the description of the first and second embodiments, the lower electrode of the capacitor is composed of the two electrode portions. However, the present invention is applicable to a lower electrode of a capacitor formed of at least three electrode portions.

A lower electrode formed of three electrode portions will be described with reference to FIG. 12.

A process of manufacturing a capacitor according to the present embodiment is the same as that according to the first embodiment from the beginning to a halfway step, that is, the steps shown in FIGS. 3 to 7 are common to both processes. After the step shown in FIG. 7, tungsten 30 is deposited on interlayer insulating film 5 so as to fill the interior of opening 6. Thereafter, the tungsten on the top surface portion of interlayer insulating film 5 is removed.

Thereafter, manufacturing steps similar to those for cylinder type electrode 10 according to the first embodiment (steps shown in FIGS. 4 to 7) are applied to form another cylinder type electrode 31 on cylinder type electrode 10.

Both cylinder type electrodes 31 and 10 are formed of a conductive film composed of a stack film (TiN/Ti) of titanium nitride and titanium. Tungsten 30 filled inside cylinder type electrode 10 is not exposed in the connection portion between cylinder type electrode 10 and 31.

A technique similar to that described above can be used to form a lower electrode of a capacitor composed of at least four electrode portions.

The manufacturing method according to the present invention can be used to increase the number of electrode stages included in the lower electrode of the capacitor. This facilitates an increase in capacitance value while inhibiting possible leakage current from the capacitor.

### Fourth Embodiment

An embodiment will be described in which DRAM is formed as an example of the semiconductor device according to the present invention.

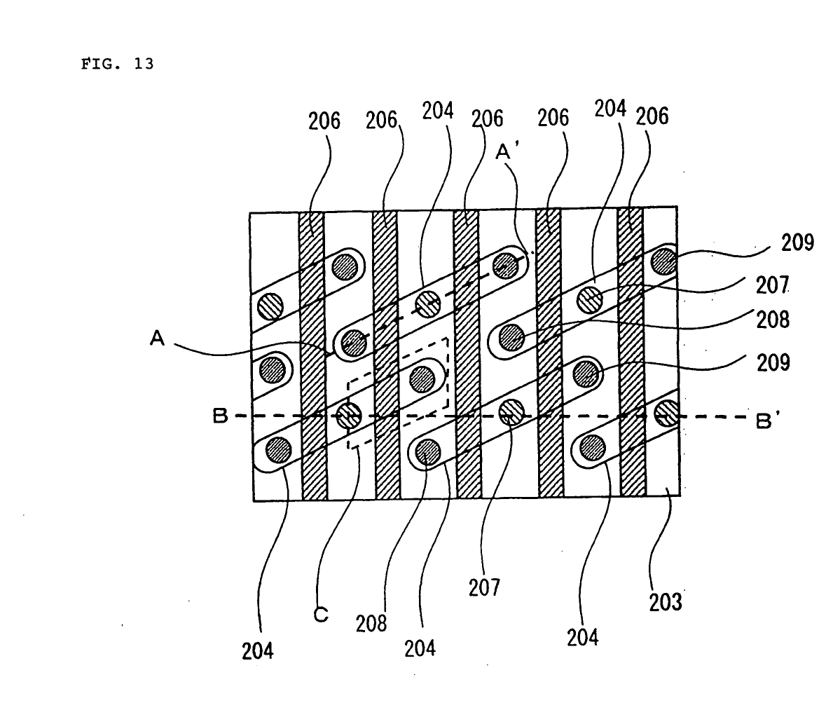

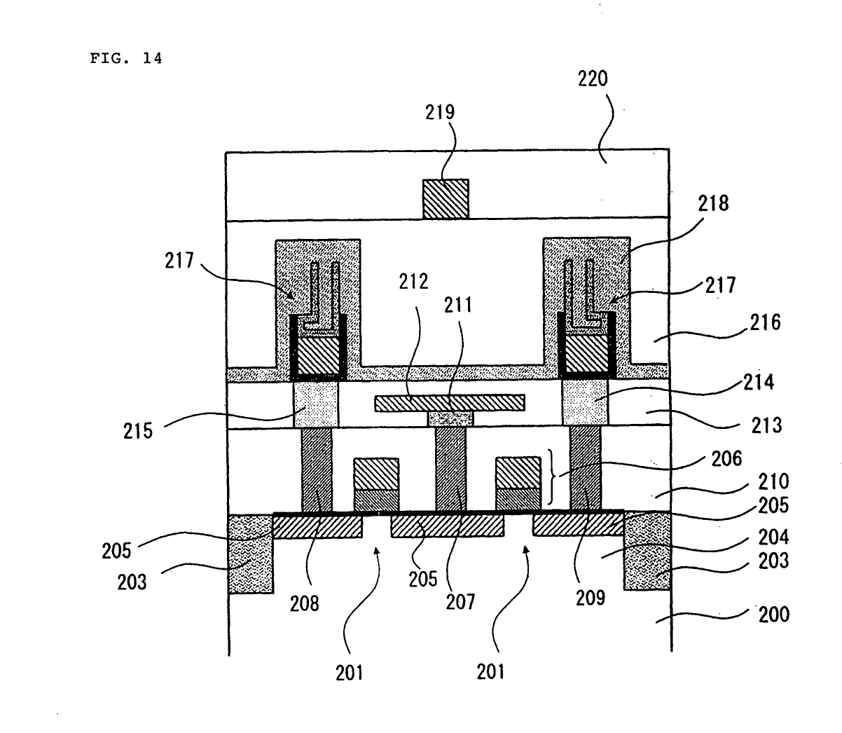

FIG. 13 is a plan view schematically showing a part of a memory cell in the DRAM. For description of the layout, only portions relating to transistors are shown, with capacitor portions omitted.

In FIG. 13, plurality of active regions (diffusion layer regions) 204 are regularly arranged on a semiconductor substrate (not shown in the drawings). Active regions 204 are partitioned by isolation regions 203. Isolation regions 203 are formed by an STI (Shallow Trench Isolation) method. Plurality of gate electrodes 206 are arranged so as to cross active regions 204. Gate electrodes 206 function as word lines for the DRAM. Impurities such as phosphorous are ion-injected into a region of each of active regions 204 which are not covered with gate electrode 206. The region thus forms an N-type diffusion layer region. The N-type diffusion layer region functions as a source/drain region of a transistor. A portion of FIG. 13 which is enclosed by dashed line C forms one MOS transistor.

Contact plug 207 is provided in the central portion of each active region 204 that is in contact with an N-type diffusion layer region on the surface of active region 204. Contact plugs 208 and 209 are provided at the respective opposite ends of each active region 204 that is in contact with the N-type diffusion layer region on the surface of active region 204. Contact plugs 207, 208, and 209 are denoted by different reference numerals for the purpose of description but can be simultaneously formed during the actual manufacture.

In this layout, to allow memory cells to be densely arranged, two adjacent transistors share one contact plug 207.

In the subsequent step, wiring layers (not shown in the drawings) each of which is in contact with corresponding contact plugs 207 and each of which is orthogonal to corresponding gate electrodes 206 are formed in a direction shown by line B-B'. The wiring layers function as bit lines for the DRAM.

Furthermore, the capacitor (not shown in the drawings) described above in the embodiments is connected to each of contact plugs 208 and 209.

FIG. 14 is a sectional view of a memory cell in the completed DRAM. FIG. 14 also corresponds to a cross section taken along portion A-A' in FIG. 13.

As shown in FIG. 14, MOS transistor 201 is formed on the surface of semiconductor substrate 200 composed of P-type silicon. Gate electrodes 206 of MOS transistor 201 that functions as word lines are present on semiconductor substrate 200.

N-type impurity layers 205 are formed in the surface portion of active region 204 in contact with contact plugs 207, 208, and 209, respectively. The material for contact plugs 207, 208, and 209 may be polycrystalline silicon doped with phosphorous.

Interlayer insulating film 210 is provided on MOS transistor 201.

Contact plug 207 is connected, via a separate contact plug 211, to wiring layer 212 that functions as a bit line. Tungsten may be used as a material for wiring layer 212.

Furthermore, contact plugs 208 and 209 are connected, via separate contact plugs 214 and 215, to a lower electrode of capacitor element 217 according to the present invention. The structure of capacitor element 217 has been described in the first embodiment in detail.

Upper electrode 218 included in capacitor element 217 is formed on interlayer insulating film 210 via interlayer insulating film 213 that insulates wires from each other. Moreover, upper electrode 218 is covered with interlayer insulating layer 216.

Moreover, wiring layer 219 formed using aluminum and surface protection film 220 may be formed on interlayer insulating film 216.

In this semiconductor device, turning on MOS transistor 201 allows determination, via bit line (wiring layer 212), of whether or not any charge is accumulated in capacitor element 217. That is, the semiconductor device operates as a memory cell for a DRAM which can perform an information storing operation.

As described above, capacitor element 217 can inhibit possible leakage current. Thus, the present invention enables the easy manufacture of a high-performance DRAM with memory cells that offer an excellent data holding property (refresh property).

In the present embodiment, the capacitor structure in the DRAM has been described. However, the present invention is not limited to the DRAM. The technical concept of the present invention is applicable to any capacitor structure that has a lower electrode constructed by connecting a plurality of electrode portions together so that the electrode portions are stacked.

Although the inventions has been described above in connection with several preferred embodiments thereof, it will be appreciated by those skilled in the art that those embodiments are provided solely for illustrating the invention, and should not be relied upon to construe the appended claims in a limiting sense.

What is claimed is:

1. A semiconductor device comprising a capacitor that includes a capacitive insulating film sandwiched between a first electrode and a second electrode, the second electrode being disposed over the first electrode, the first electrode being constructed by connecting a plurality of electrode portions together, a lower electrode portion of the adjacent electrode portions comprising columnar tungsten,
wherein the lower electrode portion further comprises a conductive film covering a side surface and a bottom surface of the tungsten, and
a top surface of the tungsten is covered with a bottom portion of an upper electrode portion of the first electrode.

2. The semiconductor device according to claim 1, wherein there is a recess in an upper part of the lower electrode portion, the recess being formed by the top surface of the tungsten and the conductive film, and
a bottom part of the upper electrode portion is located in the recess so as to cover the top surface of the tungsten.

3. The semiconductor device according to claim 2, wherein the upper electrode portion is formed of a cylindrical conductive film shaped like a boot.

4. The semiconductor device according to claim 3, wherein an insulating material is filled inside the upper electrode portion of the first electrode.

5. The semiconductor device according to claim 1, further comprising:
a semiconductor substrate; and
an active region formed on a surface of the semiconductor substrate and defined by an isolation region, wherein
the lower electrode portion of the first electrode is electrically connected to the active region.

6. The semiconductor device according to claim 5, which operates as a memory cell for a DRAM, the memory cell being configured to store date into the capacitor.

7. A semiconductor device comprising:
a tungsten plug;
a first conductive film formed over surfaces of the tungsten plug other than a top surface thereof;
a second conductive film formed over the top surface of the tungsten plug; and
a third conductive film formed opposite the first and second conductive films with an intervention of a capacitive insulating film therebetween,
wherein a capacitor is formed such that one electrode comprises the first and second conductive films and another electrode comprises the third conductive film.

8. The semiconductor device according to claim 7, wherein the second conductive film extends upward from the tungsten plug in cylindrical form.

9. The semiconductor device according to claim 7, wherein the first, second, and third conductive films are formed of a material containing titanium nitride.

10. The semiconductor device according to claim 7, including a memory cell for a DRAM formed by connecting the capacitor to either source electrode or drain electrode of a MOS transistor.

11. A method for manufacturing a semiconductor device comprising:
preparing a semiconductor substrate;
forming a first interlayer insulating film above the semiconductor substrate;
forming a first contact hole penetrating the first interlayer insulating film;
forming a first conductive film as a barrier layer on an inner surface of the contact hole;
filling tungsten inside the contact hole with the first conductive film formed therein;
forming a second interlayer insulating film on the first interlayer insulating film so that the second interlayer insulating film covers a plug type electrode comprising the barrier film and the tungsten;
forming a second contact hole penetrating the second interlayer insulating film to expose a part of an upper surface of the plug type electrode;
removing an upper part of the tungsten of the plug type electrode through the second contact hole to form a cavity portion in the plug type electrode;
forming a second conductive film that serves as a cylinder type electrode, on a side surface of the second contact hole and an inner surface of the cavity portion;
removing the first interlayer insulting film and the second interlayer insulating film so as to expose all of the cylinder type electrode and a part of the plug type electrode;
forming a capacitive insulating film on exposed surfaces of the cylinder type electrode and the plug type electrode; and
forming a third conductive film on the capacitive insulating film.

12. The method for manufacturing the semiconductor device according to claim 11, further comprising, after forming the second conductive film, filling an insulating material inside the cylinder type electrode formed by the second conductive film.

13. The method for manufacturing the semiconductor device according to claim 11, wherein the first and the second conductive films are formed of a material containing titanium nitride.

14. The method for manufacturing the semiconductor device according to claim 11, further comprising, before removing the first interlayer insulating film and the second interlayer insulating film, forming a support film that prevents the cylinder type electrode from collapsing.
